(19) United States
(12) Patent Application Publication
(10) Pub. No.: US 2025/0212312 A1
(43) Pub. Date: Jun. 26, 2025

(54) PRINTED CIRCUIT BOARD WITH A BUILT-IN VAPOR CHAMBER

(71) Applicant: Intel Corporation, Santa Clara, CA (US)

(72) Inventors: Jose DIAZ MARIN, San Jose (CR); Francini MONGE VALVERDE, San Marcos de Tarrazú (CR); Arturo NAVARRO ALVAREZ, San Isidro (CR); Elkjaer PORRAS RODRIGUEZ, Alajuela (CR); Luis Carlos SANCHEZ HERRERA, Canoas (CR); Min Suet LIM, Gelugor (MY)

(21) Appl. No.: 18/389,821

(22) Filed: Dec. 20, 2023

(51) Int. Cl. H05K 1/02; H05K 3/46

(52) U.S. Cl. CPC H05K 1/0201; H05K 3/4644; H05K 2201/064

(57) ABSTRACT

A printed circuit board, PCB, comprises a plurality of substrate layers. The PCB comprises a first laminate comprising a hot region of a vapor chamber, configured to absorb heat from at least one component coupled to an outermost substrate of the PCB. The PCB further comprises a second laminate comprising a cold region of the vapor chamber, configured to be a condensing substrate. Additionally, the PCB comprises a middle laminate between the first and second laminates, the middle laminate comprising the vapor chamber.

### BACKGROUND

While a size of an integrated circuit (IC) package decreases, heat or power dissipation of the IC may increase over the year so that cooling from the top of the IC may result in unacceptably big cooling bodies. A relatively new approach is additional or alternative cooling from the bottom of the IC package. It utilizes a vapor chamber or heat pipe within a printed circuit board (PCB) for dissipating heat directly transferred to the PCB. However, the volume of the PCB may be affected by the implemented heat dissipation system and the price of pre-built vapor chambers to be inserted into the PCB may be high. Hence, there may be a need for improved heat dissipation.

### BRIEF DESCRIPTION OF THE FIGURES

Some examples of apparatuses and/or methods will be described in the following by way of example only, and with reference to the accompanying figures, in which

FIG. 1 illustrates an example of a PCB.

FIG. 2 illustrates an isometric exploded illustration of the PCB.

FIG. 3 illustrates an example of the PCB prepared to include a working fluid and having an aperture and an associated seal.

FIG. 4 illustrates a condensing process in the PCB.

FIG. 5 illustrates an example of the PCB comprising a wire mesh.

FIG. 6 illustrates an example of a method for fabricating the PCB with a built-in vapor chamber.

FIG. 7 illustrates an example of a computing device comprising the PCB.

### DETAILED DESCRIPTION

Some examples are now described in more detail with reference to the enclosed figures. However, other possible examples are not limited to the features of these embodiments described in detail. Other examples may include modifications of the features as well as equivalents and alternatives to the features. Furthermore, the terminology used herein to describe certain examples should not be restrictive of further possible examples.

Throughout the description of the figures same or similar reference numerals refer to same or similar elements and/or features, which may be identical or implemented in a modified form while providing the same or a similar function. The thickness of lines, layers and/or areas in the figures may also be exaggerated for clarification.

When two elements A and B are combined using an “or”, this is to be understood as disclosing all possible combinations, i.e. only A, only B as well as A and B, unless expressly defined otherwise in the individual case. As an alternative wording for the same combinations, “at least one of A and B” or “A and/or B” may be used. This applies equivalently to combinations of more than two elements.

If a singular form, such as “a”, “an” and “the” is used and the use of only a single element is not defined as mandatory either explicitly or implicitly, further examples may also use several elements to implement the same function. If a function is described below as implemented using multiple elements, further examples may implement the same function using a single element or a single processing entity. It is further understood that the terms “include”, “including”, “comprise” and/or “comprising”, when used, describe the presence of the specified features, integers, steps, operations, processes, elements, components and/or a group thereof, but do not exclude the presence or addition of one or more other features, integers, steps, operations, processes, elements, components and/or a group thereof.

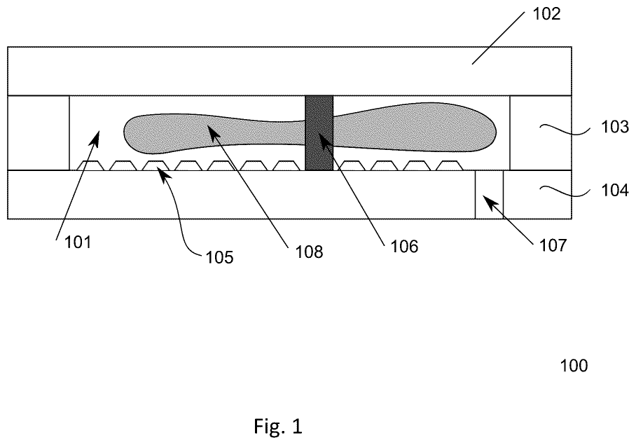

A PCB comprising a built-in vapor chamber configured to transfer heat from components coupled to the PCB will be illustrated with respect to FIGS. 1 to 3.

FIG. 1 illustrates an exemplary cross-sectional diagram of a PCB 100 comprising a first laminate 102, a middle laminate 103, and a second laminate 104. The middle laminate 103 comprises a built-in vapor chamber 101.

According to an example, any of the first laminate 102, the middle laminate 103, the second laminate 104 may optionally comprise one or multiple substrate layers. The built-in vapor chamber 101 is formed by the three laminates 102-104.

According to an example, the built-in vapor chamber comprised in the PCB can be understood as the middle laminate has a recess defining a shape of the vapor chamber 101.

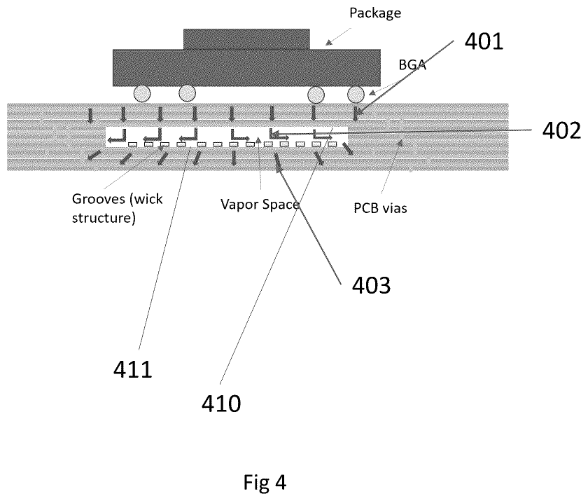

According to an example, at least one of the first laminate 102 and the second laminate 104 optionally comprises a micro-structured surface facing the vapor chamber 101. The micro-structured surface comprises multiple wicks or grooves 105 extending from the surface into the vapor chamber. For an exemplary purpose, the wick structure 105 is displayed on the surface of the second laminate 104 facing the vapor chamber 101. The wick structure 105 is configured to provide or generate capillarity. The capillarity may be understood as a process of a liquid flowing in a narrow space without an assistance of any external forces. The wick structure 105 is associated with a heat dissipation process of the vapor chamber 101, which will be further explained in FIG. 4.

According to an example, at least one pillar 106 is optionally comprised in the vapor chamber 101 configured to increase structural strength. The pillar 106 may be understood as a tall wick which couples the first laminate 102 and the second laminate 104.

According to an example, a working fluid 108 is optionally present within the vapor chamber 101.

According to an example, some or all holes in the three laminates 102-104 are plated using a conductive material, e.g. copper, preventing leaks of the working fluid 108 within the vapor chamber 101.

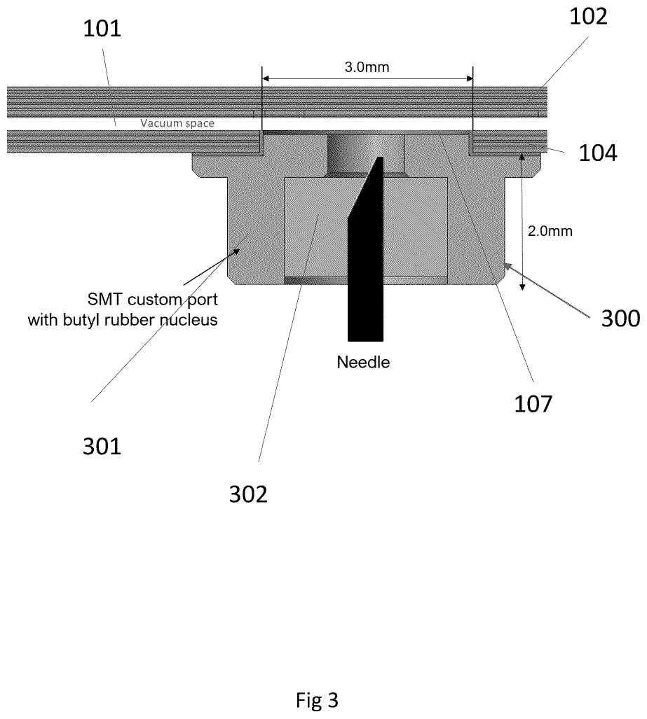

According to an example, an aperture 107 is optionally comprised in the PCB 100, configured to inject the working fluid 108 into the built-in vapor chamber 101. The aperture 107 extends from a surface of the PCB 100 into the vapor chamber 101, which will be further explained in FIG. 3. The built-in vapor chamber 101 uses the energy of phase transitions of the working fluid 108 and the circulation of the working fluid 108 to transfer heat between the first laminate 102 and the second laminate 104, which will be further explained in FIG. 4.

The vapor chamber 101 may not need an additional space to be built within the PCB 100 since it is formed by the three laminates 102-104 comprised in the PCB 100. Since a volume of a heat dissipation system affects a size of an electronic package for cooling, the PCB 100 with the built-in vapor chamber 101 may reduce the volume of the electronic package. Additionally, since the vapor chamber 101 may be formed during the PCB 100 fabrication process instead of being inserted into the PCB 100 as an external body, it may reduce the cost of a heat dissipation system implementation by reducing the fabrication step.

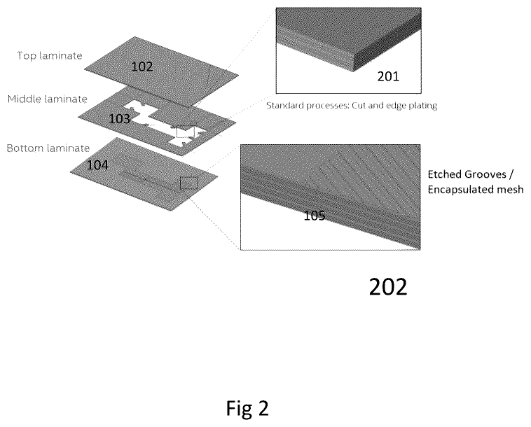

The PCB 100 is further illustrated in the context of FIG. 1 with respect to FIGS. 2 and 3.

FIG. 2 illustrates an isometric exploded illustration of the PCB of FIG. 1. For an exemplary purpose, the first laminate 102, the middle laminate 103, and the second laminate 104 are illustrated separately. As an example, the micro-structure is only displayed on the surface of the second laminate 104. The micro-structure faces the vapor chamber 101. A magnified cross-sectional illustration of the middle laminate 201 depicts a plated surface of the middle laminate 103 facing the vapor chamber 101. Any holes on the surfaces of the first laminate 102, the middle laminate 103, and the second laminate 104 facing the vapor chamber are plated with a conductive material, e.g. with copper. The recess defining the shape of the vapor chamber may have various shapes. An exemplary wick structure 105 is further illustrated in the magnified view 202. The wick structure 105 may be provided by etching the surface of the second laminate 104 facing the vapor chamber 101. The etched surface may, for example, be plated with copper. The pillar 106, the aperture 107, and the working fluid 108 are illustrated in FIG. 1 may also be present. However, they are not illustrated in FIG. 2 which focusses on different aspects.

FIG. 3 further illustrates an example of the aperture 107 and a seal 300 in the PCB 100 in the context of FIG. 1. The seal 300 comprises a port 301 and an elastomer 302 for self-sealing. An elastomer may be understood as a polymer with viscoelasticity, e.g. butyl rubber. The seal 300 is coupled with the aperture 107 configured to seal the vapor chamber 101 and to inject the working fluid, which may be introduced through the elastomer 302 using a hollow tube with one sharp tip, e.g. a needle.

A heat dissipation process from a hot region to a cold region within the built-in vapor chamber of FIGS. 1 to 3 will be explained using FIG. 4.

FIG. 4 illustrates an exemplary condensation process in the built-in vapor chamber 101 within the PCB 100. Condensation may be understood as a process by which a state of matter is changed from a gas state into a liquid state. For example, a hot region 410 is a surface of the first laminate 102 facing the vapor chamber 101. A component, for example a chip, coupled to a surface of the first laminate 102 of the PCB generates heat and, hence, may be viewed as a heat source. The heat generated by the component is transmitted to the hot region 410 via the first laminate 102 coupled to the component. The heat transmitting process from the heat source is illustrated in 401. The working fluid within the vapor chamber 101 absorbs heat from the hot region 410 and boils in the process, absorbing the heat of vaporization. A cold region 411 is a surface of the second laminate 104 facing the vapor chamber 101. The working fluid condenses at the cold region 411 and the transferred heat is absorbed by the second laminate 104 to be dissipated also at the side of the PCB 100 that is opposite from the heat source. The heat dissipation process is illustrated in 403. The wick structure 105 returns the condensed working fluid to the hot region 410 of the first laminate 101 by the capillary force providing the circulation of the working fluid 402.

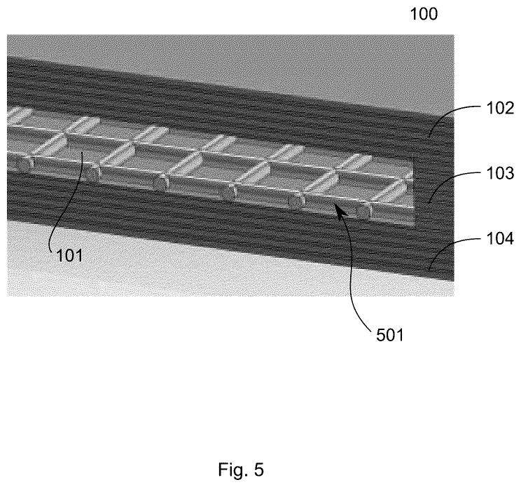

FIG. 5 illustrates a magnified cross-sectional view of the PCB 100 comprising a wire mesh 501 within the vapor chamber 101. A wire mesh may provide an additional capillarity for the condensation process in the context of FIG. 4, adding additional porosity to the wick structure 105. The porosity of the wire mesh may be understood as a fraction of the void/holes in the wire mesh. The capillarity or capillary rise is inversely proportional to a width of a structure wherein the working fluid may be comprised. The working fluid 108 illustrated in FIG. 1 may also be present. However, it is not illustrated in FIG. 5 which focusses on different aspects. Therefore, the additional porosity provided by the wire mesh 501 may improve the circulation of the working fluid within the vapor chamber 101 by increasing the capillarity.

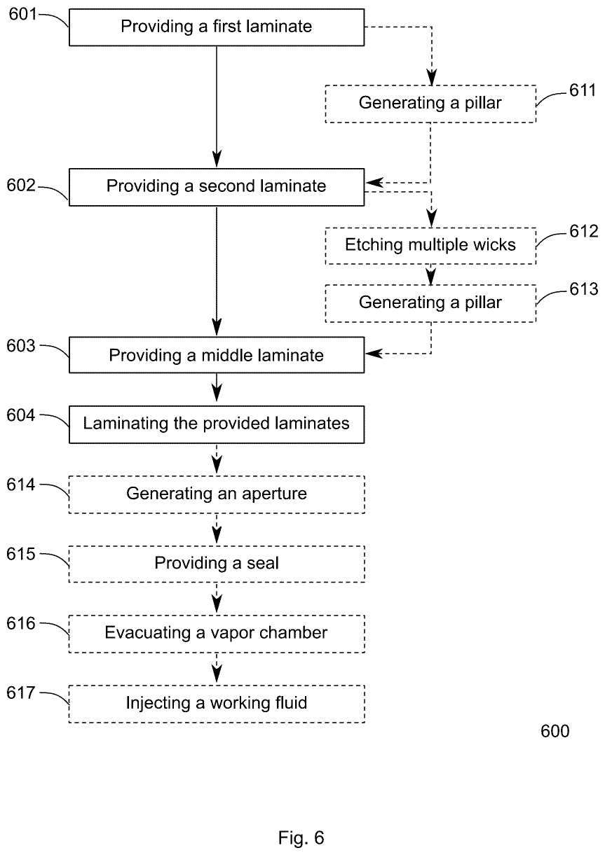

FIG. 6 illustrates a method 600 to fabricate a PCB with a built-in vapor chamber. The method 600 comprises providing a first laminate of the PCB 601. Further, the method 600 comprises providing a second laminate of the PCB having a micro-structured surface in an area of the built-in vapor chamber 602. Additionally, the method 600 comprises providing a middle laminate having a recess with the shape of the vapor chamber 603. The method further comprises laminating the provided first, middle and second laminates such that the middle laminate is place in between the first laminate and the second laminate 604.

According to an example, providing any of the first, the second, and the middle laminates which optionally comprises multiple substrate layers.

According to an example, providing the second laminate of the PCB which optionally comprises etching multiple wicks extending from the surface of the second laminate 612.

According to an example, the method 600 optionally comprises generating at least one pillar on one of the first laminate 611 or the second laminate 613, the pillar extending to the surface of the respective laminate by a thickness of the vapor chamber.

According to an example, the method 600 optionally comprises generating an aperture extending from a surface of the PCB into the vapor chamber 614.

According to an example, the method 600 optionally comprises providing a seal for the aperture 615.

According to an example, the method 600 optionally comprises evacuating the vapor chamber through the seal 616.

According to an example, the method 600 optionally comprises injecting a working fluid into the vapor chamber through the seal 617.

The method 600 may enable fabrication of a PCB with a built-in vapor chamber to provide direct cooling from the bottom of an electronic package instead of utilizing a vapor chamber coupled to the PCB externally or implementing an externally built vapor chamber into the PCB. Additionally, the method 600 may reduce the cost of a PCB fabrication with heat dissipation system by comprising forming of the built-in vapor chamber within the PCB manufacturing process.

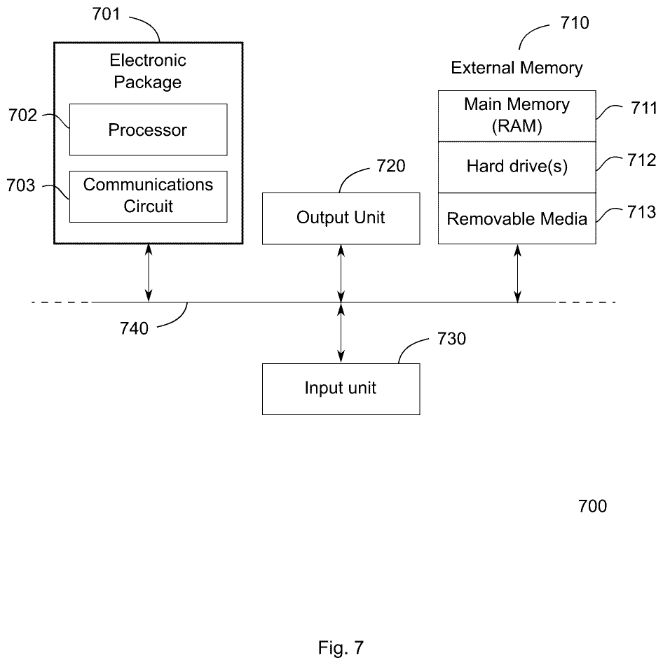

The method 600 may comprise one or more additional optional features corresponding to one or more aspects of the proposed technique or one or more examples described below. More details and aspects of the PCB 100 will be explained with respect to FIG. 7.

FIG. 7 illustrates a block diagram of components of a computing device 700 comprising an example of the PCB with the built-in vapor chamber. Examples of the computing device 700 may be personal computers, tablet computers, portable devices, mobile telephones, game devices, MP3 or other digital music players. In this example, the computing device 700 comprises a data processing system that comprises a system bus 740 to couple the various components of the computing device 700. The system bus 740 provides communications links among the various components of the computing device 700 and may be implemented as a single bus, as a combination of busses, or in any other suitable manner.

An electronic package 701 as describe herein may be coupled to system bus 740. The electronic package 701 may comprise any circuit or combination of circuits. In one embodiment, the electronic package 701 comprises a processor 702 soldered to e.g. the PCB with the built-in vapor chamber which can be of any type. As used herein, “processor” means any type of computational circuit, such as but not limited to a microprocessor, a microcontroller, a complex instruction set computing (CISC) microprocessor, a reduced instruction set computing (RISC) microprocessor, a very long instruction word (VLIW) microprocessor, a graphics processor, a digital signal processor (DSP), multiple core processor, or any other type of processor or processing circuit.

Other types of circuits that may be comprised in the electronic package 701 are a custom circuit, an application-specific integrated circuit (ASIC), or the like, such as, for example, one or more circuits (such as a communications circuit 703) for use in wireless devices like mobile telephones, tablet computers, laptop computers, two-way radios, and similar electronic systems. The IC can perform any other type of function.

The computing device 700 may further comprise an external memory 710, which in turn may comprise one or more memory elements suitable to the particular application, such as a main memory 711 in the form of random access memory (RAM), one or more hard drives 712, and/or one or more drives that handle removable media 713 such as compact disks (CD), flash memory cards, digital video disk (DVD), and the like.

The computing device 700 may also comprise an output unit 720 such as a display and/or speaker, and input unit 730, which may be a mouse, trackball, touch screen, voice-recognition device, or any other device that allows a system user to input information into and receive information from the computing device 700.

The examples described herein may be summarized as follows:

An example (e.g. example 1) relates to a PCB, comprising a plurality of substrate layers, the PCB comprising: a first laminate comprising a hot regions of a vapor chamber, configured to absorb heat from at least one component coupled to an outermost substrate of the PCB; a second laminate comprising a cold region of the vapor chamber, configured to be a condensing substrate; and a middle laminate between the first and the second laminates, the middle laminate having a recess defining a shape of the vapor chamber.

Another example (e.g. example 2) relates to a previously described example (e.g. example 1), wherein any of the first, the second, and the middle laminates comprises substrate layers.

Another example (e.g. example 3) relates to a previously described example (e.g. example 1) wherein the vapor chamber is at least partially formed by a recess in the middle laminate.

Another example (e.g. example 4) relates to a previously described example (e.g. example 1), wherein at least one of the first and the second laminates comprises a micro-structured surface facing the vapor chamber.

Another example (e.g. example 5) relates to a previously described example (e.g. example 2), wherein the micro-structured surface comprises multiple wicks extending from the surface into the vapor chamber.

Another example (e.g. example 6) relates to a previously described example (e.g. any one of examples 1 to 4), furthering comprising at least one pillar extending from the first laminate to the second laminate.

Another example (e.g. example 7) relates to a previously described example (e.g. any one of examples 1 to 5), further comprising a working fluid contained within the vapor chamber.

Another example (e.g. example 8) relates to a previously described example (e.g. any one of examples 1 to 6), further comprising an aperture extending from a surface of the PCB into the vapor chamber.

Another example (e.g. example 9) relates to a previously described example (e.g. example 8), further comprising a seal for the aperture.

Another example (e.g. example 10) relates to a previously described example (e.g. any one of examples 1 to 8), wherein the vapor chamber comprises a wire mesh.

Another example (e.g. example 11) relates to a previously described example (e.g. example 1), wherein any holes on the surfaces of the first, second, and middle laminates facing the vapor chamber are plated with a conductive material.

Another example (e.g. example 12) relates to a method for fabricating a printed circuit board, PCB, with a built-in vapor chamber, comprising: providing a first laminate of the PCB; providing a second laminate of the PCB, the second laminate having a micro-structured surface in an area of the vapor chamber; providing a middle laminate comprising the vapor chamber; laminating the provided first, middle, and second laminates such that the middle laminate is placed in between the first laminate and the second laminate.

Another example (e.g. example 13) to a previously described example (e.g. example 12), wherein any of the first, second and middle laminates provided comprises substrate layers.

Another example (e.g. example 14) to a previously described example (e.g. example 12), wherein providing the second laminate of the PCB comprises etching multiple wicks extending from the surface of the second laminate.

Another example (e.g. example 15) to a previously described example (e.g. example 12 or 13), further comprising generating at least one pillar on one of the first laminate or the second laminate, the pillar extending to the surface of the respective laminate by a thickness of the vapor chamber.

Another example (e.g. example 16) to a previously described example (e.g. any of examples 12 to 14), further comprising generating an aperture extending from a surface of the PCB into the vapor chamber.

Another example (e.g. example 17) to a previously described example (e.g. example 16), further comprising providing a seal for the aperture.

Another example (e.g. example 18) to a previously described example (e.g. example 17), further comprising evacuating the vapor chamber through the seal.

Another example (e.g. example 19) to a previously described example (e.g. example 18), further comprising injecting a working fluid into the vapor chamber through the seal.

Another example (e.g. example 20) relates to a computing device comprising a PCB according to any one of examples 1 to 11 and an IC mounted on the PCB.

Another example (e.g. example 21) to a previously described example (e.g. example 20), wherein the integrated circuit is mounted on top of the vapor chamber.

More details and aspects of the method are mentioned in connection with the proposed concept or one or more examples described above (e.g. FIGS. 1-7). The method may comprise one or more additional optional features corresponding to one or more aspects of the proposed concept or one or more examples described above.

A block diagram may, for instance, illustrate a high-level circuit diagram implementing the principles of the disclosure. Similarly, a flow chart, a flow diagram, a state transition diagram, a pseudo code, and the like may represent various processes, operations or steps, which may, for instance, be substantially represented in computer readable medium and so executed by a computer or processor, whether or not such computer or processor is explicitly shown. Methods disclosed in the specification or in the claims may be implemented by a device having means for performing each of the respective acts of these methods.

It is to be understood that the disclosure of multiple acts, processes, operations, steps or functions disclosed in the specification or claims may not be construed as to be within the specific order, unless explicitly or implicitly stated otherwise, for instance for technical reasons. Therefore, the disclosure of multiple acts or functions will not limit these to a particular order unless such acts or functions are not interchangeable for technical reasons. Furthermore, in some examples a single act, function, process, operation or step may include or may be broken into multiple sub-acts, -functions, -processes, -operations or -steps, respectively. Such sub acts may be included and part of the disclosure of this single act unless explicitly excluded.

Furthermore, the following claims are hereby incorporated into the detailed description, where each claim may stand on its own as a separate example. While each claim may stand on its own as a separate example, it is to be noted that—although a dependent claim may refer in the claims to a specific combination with one or more other claims—other examples may also include a combination of the dependent claim with the subject matter of each other dependent or independent claim. Such combinations are explicitly proposed herein unless it is stated that a specific combination is not intended. Furthermore, it is intended to include also features of a claim to any other independent claim even if this claim is not directly made dependent to the independent claim.

What is claimed is:

1. A printed circuit board, PCB, comprising a plurality of substrate layers, the PCB comprising:
a first laminate comprising a hot region of a vapor chamber, configured to absorb heat from at least one component coupled to an outermost substrate of the PCB;
a second laminate comprising a cold region of the vapor chamber, configured to be a condensing substrate; and
a middle laminate between the first and second laminates, the middle laminate comprising the vapor chamber.

2. The PCB of claim 1, wherein any of the first, the second and the middle laminates comprises substrate layers.

3. The PCB of claim 1, wherein the vapor chamber is at least partially formed by a recess in the middle laminate.

4. The PCB of claim 1, wherein at least one of the first and the second laminates comprises a micro-structured surface facing the vapor chamber.

5. The PCB of claim 2, wherein the micro-structured surface comprises multiple wicks extending from the surface into the vapor chamber.

6. The PCB of claim 1, further comprising at least one pillar extending from the first laminate to the second laminate.

7. The PCB of claim 1, further comprising a working fluid contained within the vapor chamber.

8. The PCB of claim 1, further comprising an aperture extending from a surface of the PCB into the vapor chamber.

9. The PCB of claim 7, further comprising a seal for the aperture.

10. The PCB of claim 1, wherein the vapor chamber comprises a wire mesh.

11. The PCB of claim 1, wherein any holes on the surfaces of the first, second, and middle laminates facing the vapor chamber are plated with a conductive material.

12. A method of fabricating a printed circuit board, PCB, with a built-in vapor chamber, comprising:
providing a first laminate of the PCB;
providing a second laminate of the PCB, the second laminate having a micro-structured surface in an area of the vapor chamber;
providing a middle laminate comprising the vapor chamber;
laminating the provided first, middle, and second laminates wherein the middle laminate is placed in between the first laminate and the second laminate.

13. The method of claim 12, wherein providing any of the first, the second, and the middle laminates comprises multiple substrate layers.

14. The method of claim 12, wherein providing the second laminate of the PCB which comprises etching multiple wicks extending from the surface of the second laminate.

15. The method of claim 12, further comprising:
generating at least one pillar on one of the first laminate or the second laminate, the pillar extending to the surface of the respective laminate by a thickness of the vapor chamber.

16. The method of claim 12 further comprising:
generating an aperture extending from a surface of the PCB into the vapor chamber.

17. The method of claim 16, further comprising:
providing a seal for the aperture.

18. The method of claim 17, further comprising:
evacuating the vapor chamber through the seal.

19. A computing device comprising:
a PCB according to claim 1; and
an integrated circuit mounted on the PCB.

20. The computing device of claim 19, wherein the integrated circuit is mounted on top of the vapor chamber.
